(19) United States
(12) Patent Application Publication
(10) Pub. No.: US 2013/0301221 A1
(43) Pub. Date: Nov. 14, 2013

(54) THERMAL MANAGEMENT SYSTEM AND METHOD BETWEEN HEAT GENERATING CHIP AND HOUSING IN ELECTRONIC APPARATUS

(71) Applicant: Jones Tech Plc., Beijing (CN)

(72) Inventor: Xiaoning WU, Beijing (CN)

(21) Appl. No.: 13/928,368

(22) Filed: Jun. 26, 2013

(30) Foreign Application Priority Data
Mar. 7, 2013 (CN) 201310073369.0

(51) Int. Cl. H01L 23/38

(52) U.S. Cl. CPC H01L 23/38
USPC 361/707

(57) ABSTRACT

The present invention relates to a thermal management system and method between a heat generating chip and a housing in an electronic apparatus. The system comprises: a housing; a heat generating chip arranged in the housing, wherein an air gap between the heat generating chip and adjacent portion of the housing is not less than 5 mm, and the dominant heat transfer mode is radiation; a heat insulation layer filled in the air gap between the heat generating chip and the housing, wherein the heat insulation layer is in contact with the heat generating chip, the heat insulation layer has an area no less than that of the heat generating chip, and the heat insulation layer has a thermal conductivity not smaller than that of air.

### CROSS-REFERENCE TO RELATED APPLICATIONS

This application claims the priority benefit of Chinese patent application No. 201310073369.0, filed on Mar. 7, 2013. The entirety of the above-mentioned patent application is hereby incorporated by reference herein and made a part of specification.

### BACKGROUND OF THE INVENTION

### Field of the Invention

The present invention relates to a thermal management system and method for an electronic apparatus, especially a miniature electronic apparatus. In particular, the present invention relates to a novel thermal management for an electronic apparatus, in which the distance between a heat generating chip and a housing is generally no more than 1 centimeter, so that the heat energy produced by the heat generating chip is primarily dissipated to the housing by radiation.

### Background of the Invention

In IT products, including computers, smart phones, handwriting computers, notebook computers, servers, control chips, or any CPU and IC (Integrated Circuit) chip-based digital devices containing CPU components, with increase in data processing speed, the products increases in degree of integration and decreases in volume. One of the major technical problems in IT hardware design is how to effectively reduce junction temperature of the heat generating chip.

Especially for handheld consumer electronic apparatus, including smart phones, tablet PC, PDA, etc., people become more sensitive to temperature of the apparatus housing when using such an apparatus. Generally speaking, the temperature of housing to which the body of an operator is exposed to should be kept below 45° C., in order to ensure comfort of the operator during use. Currently, the basic idea for lowering temperature of apparatus housing is based on the principles of heat transfer. Namely, heat of the heat generating chip is rapidly dissipated to cooling elements by heat radiation and heat conduction, such as the apparatus housing, and then dissipated outside through the housing. Besides, by means of mechanical design and thermal design, heat on the apparatus housing is made to meet the design requirements.

In a traditional design, heat on the heat generating chip is well transferred to the apparatus housing by a thermal design. Since the distance between the heat generating chip and the housing is relatively small, the dominant manner for transferring is heat radiation. This is shown in FIG. 1. Therefore, a local or global overheating occurs in the apparatus housing at places corresponding to the chip. In order to avoid local overheating on the apparatus housing, the overall thermal design has to be improved or the power has to be reduced.

However, most consumer electronic apparatus is selective to temperature limit of the housing, and the portion of the housing where the housing contacts the human body must not exceed a temperature limit, while other portions of the housing can be slightly higher. Therefore, it is proposed a selective thermal management system, which achieves selective control of surface temperature at different portions of the housing, and this is of practical significance in the actual product design. Namely, it is proposed a method for dissipating heat at the cost of time, in which the time for dissipation is appropriately extended, so that no overheating occurs in the apparatus housing.

### BRIEF SUMMARY OF THE INVENTION

It is an object of the present invention to solve the above technical problem. The present invention is based on the principles of heat transfer by introducing a heat insulation layer into the existing dissipation measures. The peak heat energy produced by the heat generating chip during a short time high-power operation is prevented from being transferred by heat radiation to the housing, especially the temperature sensitive parts of the housing.

It is an object of the present invention to provide a system and method which is capable of preventing local overheating in the housing of the electronic apparatus due to local radiation intensity from the heat generating chip.

It is another object of the present invention to provide a system and method which transfers the heat produced by chip slowly to the heat insulation layer, and then slowly to the housing of the electronic apparatus, so that the heat is gradually lost. In this manner, it is possible to avoid overheating of the entire housing.

To this end, according to the present invention, the thermal management system between a heat generating chip and a housing in an electronic apparatus comprises: a housing; a heat generating chip arranged in the housing, wherein an air gap between the heat generating chip and adjacent portion of the housing is not less than 5 mm; a heat insulation layer filled in the air gap between the heat generating chip and the housing, and blocks heat radiation from the heat generating chip to adjacent portion of the housing, wherein the heat insulation layer is in contact with the heat generating chip, the heat insulation layer has an area no less than that of the heat generating chip, and the heat insulation layer has a thermal conductivity not smaller than that of air. This is shown in FIG. 1.

In a preferred embodiment of the thermal management system between a heat generating chip and a housing in an electronic apparatus, the heat insulation layer has a thermal conductivity in a range of 0.01 W/mK-0.3 W/mK.

In a preferred embodiment of the thermal management system between a heat generating chip and a housing in an electronic apparatus, the heat insulation layer comprises a first surface and a second surface which are parallel with each other, and the second surface is in contact with the housing.

In a preferred embodiment of the thermal management system between a heat generating chip and a housing in an electronic apparatus, the heat insulation layer has a size designed to cover the entire interior of the housing. This is shown in FIG. 2.

In a preferred embodiment of the thermal management system between a heat generating chip and a housing in an electronic apparatus, the electronic apparatus is a mobile phone, handheld computer, notebook computer, and/or navigator.

In a preferred embodiment of the thermal management system between a heat generating chip and a housing in an electronic apparatus, the adjacent portion of the housing is a cover plate of the electronic apparatus.

In a preferred embodiment of the thermal management system between a heat generating chip and a housing in an electronic apparatus, the heat insulation layer is of an insulating thin film material.

In a preferred embodiment of the thermal management system between a heat generating chip and a housing in an electronic apparatus, the insulating thin film material is polyimide or PE thin film.

In a preferred embodiment of the thermal management system between a heat generating chip and a housing in an electronic apparatus, the insulating thin film material has an Ag plating layer on either side.

The present invention further provides a thermal management method between a heat generating chip and a housing in an electronic apparatus, comprising: filling a heat insulation layer in an air gap of no less than 5 mm between the housing and the heat generating chip of the electronic apparatus, wherein the heat insulation layer is in contact with the heat generating chip, the heat insulation layer has an area no less than that of the heat generating chip, and the heat insulation layer has a thermal conductivity not smaller than that of air, so that the heat energy is transferred to the heat insulation layer, and then gradually dissipated through the housing, thus avoiding the heat energy is transferred to a localized region of the housing directly by radiation.

The present invention has the following beneficial effects. The heat insulation layer blocks heat radiation from the heat generating chip to the housing of the electronic apparatus, thus avoiding local overheating of the housing. The heat insulation layer has a heat transfer coefficient higher than that of air which otherwise would be present between the heat generating chip and the housing, and does not belong to a high thermal conductivity material. In this way, the heat insulation layer can dissipate slowly heat produced by the heat generating chip to the heat insulation layer, and the heat is then gradually transferred to the housing by the heat insulation layer, so that the heat is finally dissipated by the housing. Therefore, the heat insulation layer functions to block the path for heat radiation, so that the heat dissipation is uniform and delayed.

The present invention proposes a new concept and method for solving heat dissipation in a miniature handheld apparatus. According to the present invention, an insulation combination is added to the conventional conduction and convection. The distribution of temperature over the outer surface of housing is designed in a balancing manner from the view point of a system, so as to improve the customer experience. The present invention has overcome the bias of in the existing technique that the heat energy accumulated in the heat generating chip should be dissipated as soon as possible. The present inventors have considered the fact that a handheld electronic apparatus is in a standby mode for most of the time, while only in an operating mode for a few time, and that the heat generating chip itself can bear a relatively high temperature (for the heat generating chip, the temperature rises to 80-90 Celsius degrees for a short time will not affect its operating performance). Therefore, the heat produced during the short operating mode can be dissipated slowing in the standby mode. In this way, the chip cooling system is greatly simplified, and the housing will not be overheated, thus improving the customer experience.

### BRIEF DESCRIPTION OF THE DRAWINGS

FIG. 1 is a schematic view showing a thermal management system between a heat generating chip and a housing in an electronic apparatus in the prior art;

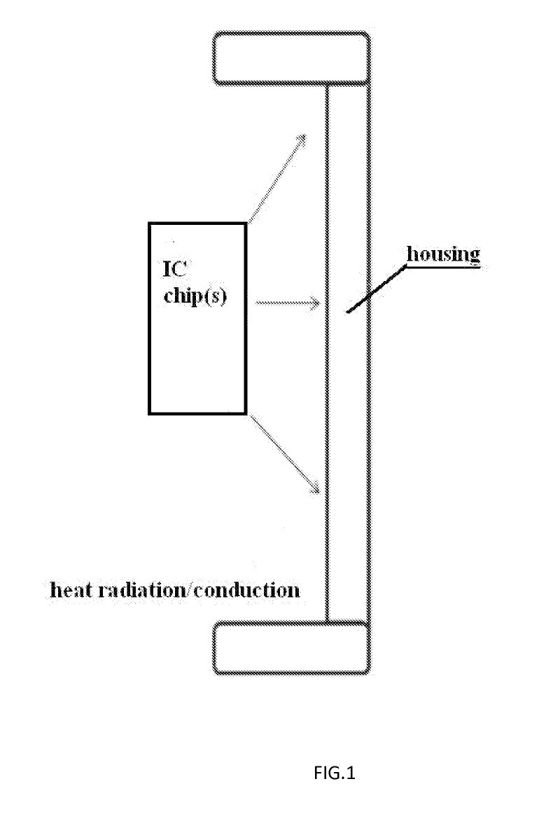

FIG. 2 is a schematic view showing a thermal management system between a heat generating chip and a housing in an electronic apparatus according to an embodiment of the present invention; and

FIG. 3 is a schematic view showing a thermal management system between a heat generating chip and a housing in an electronic apparatus according to another embodiment of the present invention.

### DETAILED DESCRIPTION OF THE INVENTION

The present invention will be further illustrated hereinafter for enabling the skilled in the art can implement the present invention by referring to the specification.

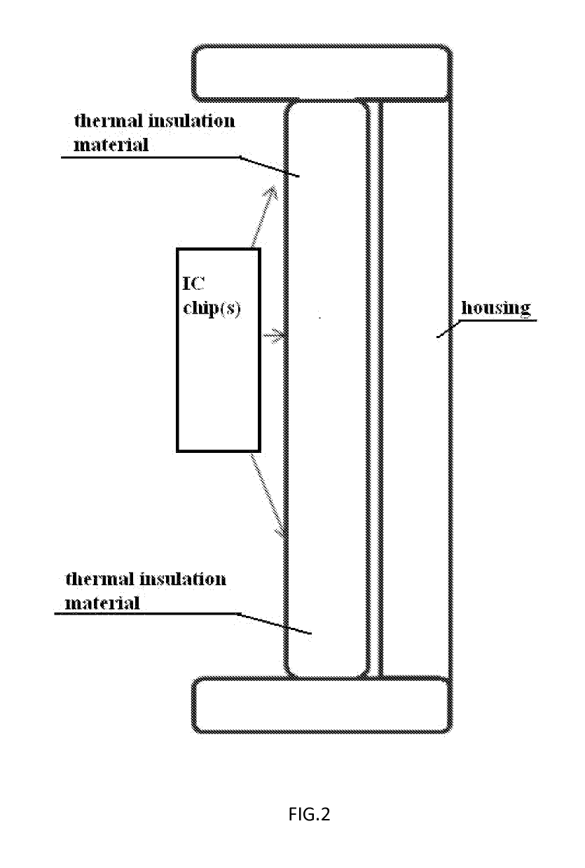

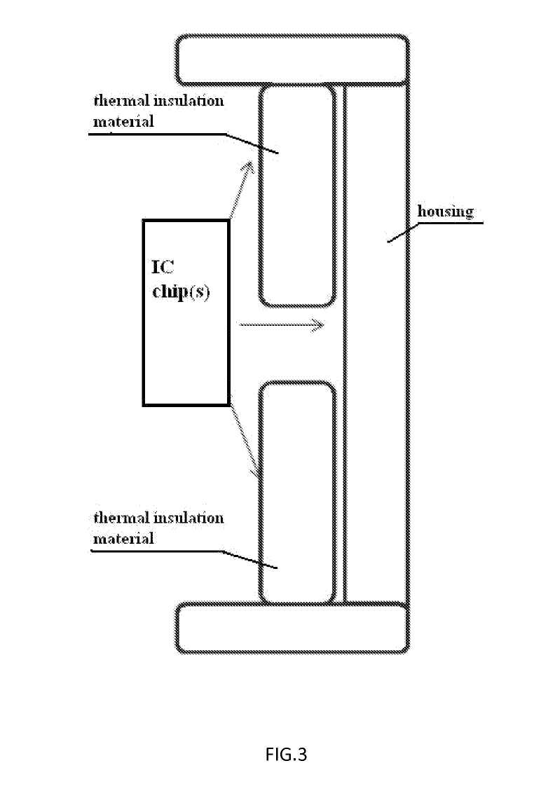

The thermal insulation material shown in FIGS. 2 and 3 is a heat insulation layer. The term “thermal insulation” as used herein means to block the heat radiated to the housing by an IC chip. The thermal insulation material itself has a relatively high heat conducting property, and can rapidly adsorb the heat produced from the IC chip. As a result, the adsorbed heat is evenly distributed over the entire thermal insulation material. The thermal insulation material (heat insulation layer) is in contact with the IC chip on one side, and with the housing on the other side, so that the adsorbed heat is transferred to the housing. As for a mobile phone or PAD, the heat is generally transferred to a cover plate which is a portion of the housing.

According to a preferred embodiment of the present invention, the thermal management system for a heat generating chip comprises:

a heat generating chip, which is commonly a component which tends to generate heat during normal operation, such as CPU, or IC chip; a housing, which is installed in the same housing as that of the heat generating component, is sensitive to temperature, has a relatively how junction temperature, and can also be an apparatus housing for preventing local overheating; and a heat insulation layer, which is arranged between the heat generating chip and the housing, and has a thermal conductivity in a range of 0.01W/mK-0.3W/mK. Generally, the heat insulation layer has an area no less than the projection of the heat generating chip on the housing. This ensures that the heat produced by the heat generating chip will be radiated to the housing as little as possible.

In a common design, the gap between the IC chip and the housing is very small and generally less than 0.2 mm. This gap is generally not filled by any material, and heat of the chip will be transferred to the housing by heat conduction in air and heat radiation. Air is a poor conductor for heat, and has a very low thermal conductivity (0.02 W/mK). However, since the distance is very small, the heat radiation plays a dominant role in the transfer process. Thus, heat can also be transferred from the chip to the housing.

During operation, the chip transfers heat to the apparatus housing. As such, heat increases in the housing, and dissipates heat to the surrounding environment. In case that the chip operates at a high power for a short time, heat in the chip increases dramatically, and the temperature of the housing also increases for a short time accordingly, so that the temperature of the housing may be too high to affect the comfort degree of the product during usage. Further, some special components installed in the apparatus housing may be more sensitive to temperature, and the rapid increase in temperature would impair its using effect.

In the present invention, it is preferred that a heat insulating thin film material is arranged between the chip and the housing. The heat insulation layer has a relatively low thermal conductivity (generally less than 0.3 W/mK), and may well block the heat conduction in the same way as air. Moreover, the heat insulation layer may also work well to block heat radiation. The heat insulation layer may be a thin film material with special color, an organic thin film material, like polyimide (PI) thin film, polyester (PET) thin film, polyethylene (PE) thin film, or a thin film material with a special plating layer (plated silver). With the heat insulation layer, it is possible to facilitate transferring the heat from IC chip to the housing by heat radiation and heat conduction. In view of the characteristic that the electronic apparatus operates at high power for a short time, and is in the standby mode for a long time, when the chip operates at a high power for a short time, it takes a longer time for heat to transfer to the housing, so as to ensure that the housing can still maintain a suitable temperature when the apparatus operates at a high power. Once the chip no longer operates at a high power for a short time, heat decreases and slowly reaches a thermal equilibrium on the housing. Thus, the temperature of the housing will not subject to a drastic fluctuation and will further improve the comfort during usage. The chip's high power operation for a short time leads to an increase in temperature. Nevertheless, the duration is not long, and the temperature increase is in a range that the chip can withstand. Therefore, even heat is dissipated slowly, it will not affect the operation efficiency and service life of the chip.

In particular, in a case in which the housing comprises some devices that are more sensitive to heat, and other components that are immune to heat, it is possible to arrange the heat insulation layer locally in the local sensitive sites. In this way, it is ensured that heat will not be transferred to the sensitive devices by heat radiation and heat conduction, and that heat will be transferred to other portions. This brings about more flexibility in design.

The basic principles, major features, and advantages of the present invention have been shown and described as above. The skilled in the art will recognize that the present invention should not be limited to the above embodiments, and the above embodiments and the detailed description only illustrate the principles of the present invention. Various variations and modifications can be made to the present invention without departing from the spirit and scope thereof. Such variations and modifications fall within the scope of the present invention as claimed. The scope of the present invention is defined in the appended claims and equivalents thereto.

What is claimed is:

1. A thermal management system between a heat generating chip and a housing in an electronic apparatus, comprising:
a housing;
a heat generating chip arranged in said housing, wherein an air gap between the heat generating chip and adjacent portion of said housing is not less than 5 mm;
a heat insulation layer, which is filled in the air gap between said heat generating chip and the housing, and blocks heat radiation from the heat generating chip to adjacent portion of the housing, wherein the heat insulation layer is in contact with the heat generating chip, the heat insulation layer has an area no less than that of the heat generating chip, and said heat insulation layer has a thermal conductivity not smaller than that of air.

2. The thermal management system between a heat generating chip and a housing in an electronic apparatus of claim 1, wherein said heat insulation layer has a thermal conductivity in a range of 0.01 W/mK-0.3 W/mK.

3. The thermal management system between a heat generating chip and a housing in an electronic apparatus of claim 1, wherein said heat insulation layer comprises a first surface and a second surface which are parallel with each other, and the second surface is in contact with the housing.

4. The thermal management system between a heat generating chip and a housing in an electronic apparatus of claim 3, wherein said heat insulation layer has a size designed to cover the entire interior of the housing.

5. The thermal management system between a heat generating chip and a housing in an electronic apparatus of claim 1, wherein said electronic apparatus is a mobile phone, handheld computer, notebook computer, and/or navigator.

6. The thermal management system between a heat generating chip and a housing in an electronic apparatus of claim 1, wherein said adjacent portion of the housing is a cover plate of the electronic apparatus.

7. The thermal management system between a heat generating chip and a housing in an electronic apparatus of claim 1, said heat insulation layer is of an insulating thin film material.

8. The thermal management system between a heat generating chip and a housing in an electronic apparatus of claim 7, said insulating thin film material is polyimide, PE thin film.

9. The thermal management system between a heat generating chip and a housing in an electronic apparatus of claim 7, said insulating thin film material has an Ag plating layer on either side.

10. The thermal management system between a heat generating chip and a housing in an electronic apparatus of claim 8, said insulating thin film material has an Ag plating layer on either side.

11. A thermal management method between a heat generating chip and a housing in an electronic apparatus, comprising:
filling a heat insulation layer in an air gap of no less than 5 mm between the housing and the heat generating chip of the electronic apparatus,
wherein the heat insulation layer is in contact with one or both of the heat generating chip and the housing, the heat insulation layer has an area no less than that of the heat generating chip, and said heat insulation layer has a thermal conductivity not smaller than that of air,
wherein heat energy produced by the heat generating chip is blocked by the heat insulation layer, so that the heat energy is transferred to the heat insulation layer, and then gradually dissipated through the housing, thus avoiding the heat energy is transferred to a localized region of the housing directly by radiation.
